(19) United States
(12) Patent Application Publication
(10) Pub. No.: US 2010/0155107 A1
(43) Pub. Date: Jun. 24, 2010

(54) INTER-LAYER CONNECTION FOR FOIL MEMS TECHNOLOGY

(75) Inventors: Geert Langereis, Eindhoven (NL); Ivar J. Boerefijn, Veldhoven (NL)

Correspondence Address: NXP, B.V.;NXP INTELLECTUAL PROPERTY & LICENSING, M/S41-SJ, 1109 MCKAY DRIVE, SAN JOSE, CA, 95131, US

(73) Assignee: NXP B.V., Eindhoven (NL)

(21) Appl. No.: 12/296,164

(22) PCT Filed: Apr. 4, 2007
(86) PCT No.: PCT/IB07/51197

§ 371 Date: Oct. 6, 2008

(30) Foreign Application Priority Data
Apr. 10, 2006 (EP) 06112417.8

(51) Int. Cl. H05K 1/00; B23K 31/02

(52) U.S. Cl. 174/254; 228/121

(57) ABSTRACT

The invention relates to a method of manufacturing conductive inter-layer connections in a microsystem built by a patterned stack of flexible foils (10). Conductive inter-layer connections (210, 300, 400) made of solder material, sputtered or evaporated material or by means of carbonization of plastic material building the isolating layer (30) of the flexible foils (10) are formed to connect patterned conductive layers (40, 50) separated by means of at least one isolating layer (30) in a conductive way in order to interconnect different parts of the microsystem in an easy way.

The present invention relates to a method of manufacturing inter-layer connection for foil MEMS technology.

U.S. Pat. No. 5,106,461 describes a method making inter-layer connections by applying a first layer of a conductive material over a substrate, forming a first layer of dielectric material over the layer of conductive material, creating openings for vias in the layer of dielectric material in desired locations, plating via posts into the via openings using the first layer of conductive material as an electrode and deposit over the dielectric and the via posts a next layer of a conductive material. This method is repeated several times and finally the substrate is removed and the first layer of conductive material is also patterned. The disadvantage of this method is that the interlayer connection has to be manufactured layer by layer. Depending on the number of layers the effort and cost of this method is unacceptable.

It is an objective of the present invention to provide a simple and cost effective method for manufacturing inter-layer connections especially suited for foil MEMS technology. This foil MEMS technology is described in detail in the European patent application 05108280.8 filed on Sep. 9, 2005 with the title “A method of manufacturing a microsystem, such a microsystem, a stack of foils comprising such a microsystem, an electronic device comprising such a microsystem and use of the electronic device”. The objective is achieved by means of a method of manufacturing inter-layer connections in a microsystem with a space, which method comprises the following steps:

providing a set (S) of at least two electrically insulating flexible foils, wherein the individual foils comprise the same foil material, and wherein a conductive layer is present on at least one side of at least two flexible foils, and wherein said conductive layers are suitable for use as an electrode or a conductor;

patterning the conductive layers so as to form electrodes or conductors;

patterning at least one flexible foil, in such a manner that at least one opening is formed;

stacking the set (S) of flexible foils;

joining the flexible foils together;

providing an electrically conducting inter-layer connections between at least two patterned conductive layers placed separated by means of at least one isolating layer of the flexible foils. The flexible foils can be joined together by bonding the flexible foils together at those positions where, when two adjacent flexible foils are in contact with each other, at least one conductive layer between the foil material of two adjacent flexible foils has been removed. The conducting inter-layer connections are needed to contact the conductive layers of flexible foils separated by isolating layers in order to enable a connection between different functional parts of a MEMS device or Microfluidic device built by patterning and stacking the flexible foil as described in the European patent application 05108280.8, between more than one MEMS devices or Microfluidic devices between a MEMS device or Microfluidic device and other devices as integrated circuits (IC).

In one embodiment of the invention at least two flexible foils are bonded to each other whereby one opening in a first flexible foils is provided to build a contact hole. If there are more than two foils bonded together the contact hole can comprise two or more aligned openings in one foil respectively. The contact hole is positioned in a way that a second conductive layer either patterned or not patterned on a second flexible foil is accessible through the contact hole. In addition there is at least one first patterned conductive layer on the first flexible foil or stack of foils with the contact hole. At least a part of this first patterned conductive layer is also freely accessible as the second conductive layer being accessible in the contact hole. There are several possibilities to enable the accessibility of the first patterned conductive layer. One possibility is that the first patterned conductive layer is the top layer of a flexible foil or of a stack of flexible foils not covered by other layers or foils. A second possibility is that the patterned conductive layer is partly covered by at least one third flexible foil in a way that the third flexible foil has an opening being aligned to the other opening or openings being part of the contact hole. The opening in the third flexible foil being part of the contact hole has a bigger extension as the other opening or openings being part of the contact hole. The first patterned conductive layer extends to the contact hole in a way that the third flexible foil does not cover parts of the patterned conductive layer in the contact hole. The top surface of the patterned conductive layer is accessible in the contact hole. A third possibility is that the patterned conductive layer is partly covered by at least one third flexible foil in a way that the third flexible foil has an opening being part of the contact hole and being aligned to the other opening or openings being part of the contact hole. The patterned conductive layer extends to the contact hole in a way that a cross section of the patterned conductive layer perpendicularly to the plane defined by the flexible foils is freely accessible in the contact hole. A conductive inter-layer connection is build between the second conductive layer accessible in the opening and the first patterned conductive layer by filling the opening with a conductive material. The latter can be done by e.g. placing a solder ball on the second conductive layer in the opening, enhancing the temperature up to the point where the solder melts and the solder flows out contacting the first patterned conductive layer extending to the vicinity of the opening. Further methods to provide the interconnection are sputtering or evaporating e.g. an electrically conductive material selected from the group aluminum, platinum, silver, gold, copper, indium tin and tantalum and patterning this sputtered or evaporated conductive layer in a way that the opening and the vicinity of the opening is covered with the conductive material building an electrically conductive inter-layer connection between the second conductive layers and the first patterned conductive.

A further embodiment of the invention is that the electrically conductive inter-layer connection is created by making the insulating layer of the flexible foil electrically conductive. This can be done by carbonization, the reduction of the in this case plastic material of the isolating layer of the flexible foil to pure carbon, of a certain part or parts of one or more flexible foil with a laser in a reducing atmosphere. One or more carbonized part or parts on different flexible foils are aligned to each other and two flexible foils with at least two patterned conductive layers are aligned with the carbonized part or parts of the flexible foils that the patterned conductive layers are in contact with the surface of one or more carbonized part or parts of the flexible foils. The carbonized area or areas build one or more electrically conductive inter-layer connections between the patterned conductive layers on the different flexible foils after bonding the foils together by means of e.g. heat and pressure as described in detail in the European patent application 05108280.8. There are different possibilities to realize the conductive inter-layer connection by means of carbonization. One Method is to carbonize parts of the flexible foils first, possibly together with the patterning of the flexible foils using the same laser as for the patterning of the flexible foils as described in the European patent application 05108280.8 and then stacking and bonding the aligned flexible foils. Another method is to stack a first flexible foil on top of a second flexible foil with an electrically conductive layer or a patterned electrically conductive track carbonize a part of the first flexible foil being in contact with the electrically conductive layer or patterned electrically conductive track of the second flexible foil and stacking a third flexible foil on top of the second flexible foil and carbonize a part of the third flexible foil at the same place where the firs flexible foil has been carbonized and repeat this procedure if necessary with further flexible foils as long as the electrically conductive inter-layer connection is built and a further conductive layer or patterned conductive layer is positioned upon the electrically conductive inter-layer connection in a way that a part of the patterned conductive layer is in electrical conductive contact with the electrically conductive inter-layer connection. A further method is to stack all flexible foils and the patterned conductive layers in a way that at least parts of two different conductive layers separated by means of at least one isolating layer of at least one flexible foil have an overlapping area looking at the perpendicular direction with respect to planes of the flexible foils and carbonize the whole stack of flexible foils by e.g. applying a laser.

The material for the conductive layer of the flexible foil is preferably selected from the group consisting of aluminum, platinum, silver, gold, copper, indium tin oxide and tantalum.

The foil material of the flexible foils where the conductive layer or layers are laminated on are preferably selected from the group consisting of polyphenyl sulphide (PPS) and polyethylene terephthalate (PET). These materials are especially suited for bonding them together by means of heat and pressure. The thickness of the flexible foils is preferably between 1 μm and 5 μm because the resolution of the structures perpendicular to the planes of the flexible foils is determined by the thickness of the flexible foils as described in the European patent application 05108280.8.

Further it is an objective of the present invention to provide a microsystem built by a set of at least two electrically insulating flexible foils stacked one on top of the other, wherein the individual foils comprise the same foil material, wherein at least two foils are provided with a patterned conductive layer, which are arranged as electrodes, wherein at least one foil is provided with a space, and wherein at least two electrodes separated by means of at least one isolating layer of the flexible foils are connected by means of a conductive inter-layer connection.

The present invention will now be explained in greater detail with reference to the figures, in which the same reference signs indicate similar parts, and in which:

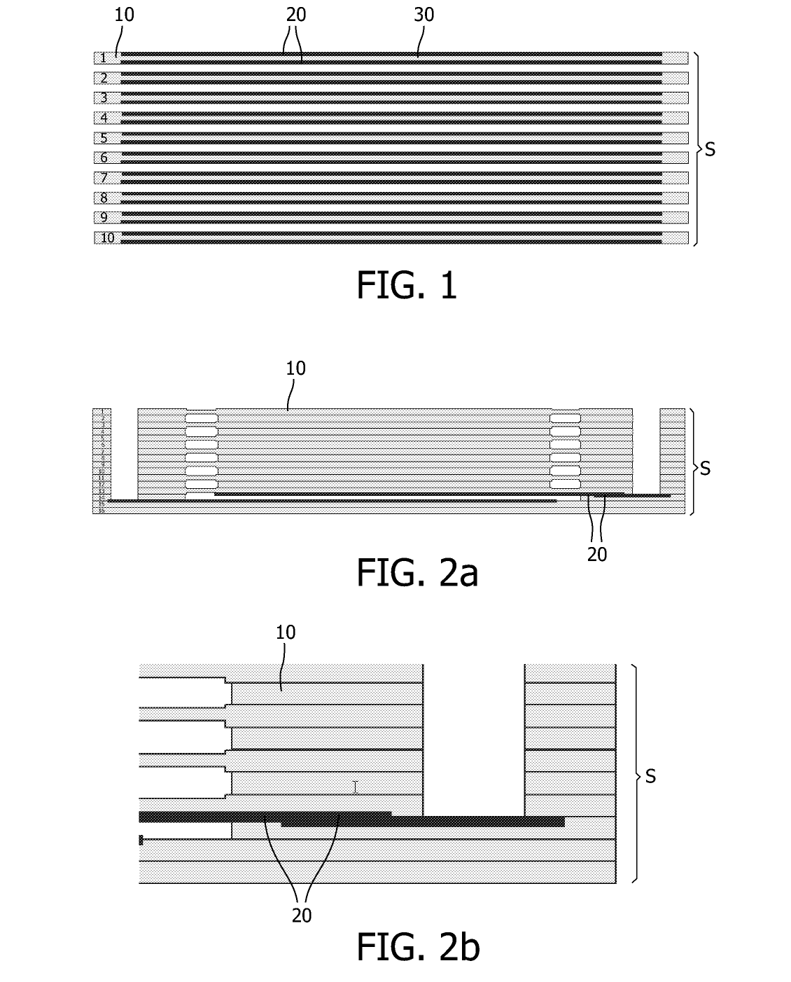

FIG. 1 shows a set (S) of flexible foils

FIG. 2a shows a foil MEMS and an inter-layer connection

FIG. 2b shows an enlarged picture of inter-layer connection depicted in FIG. 2a

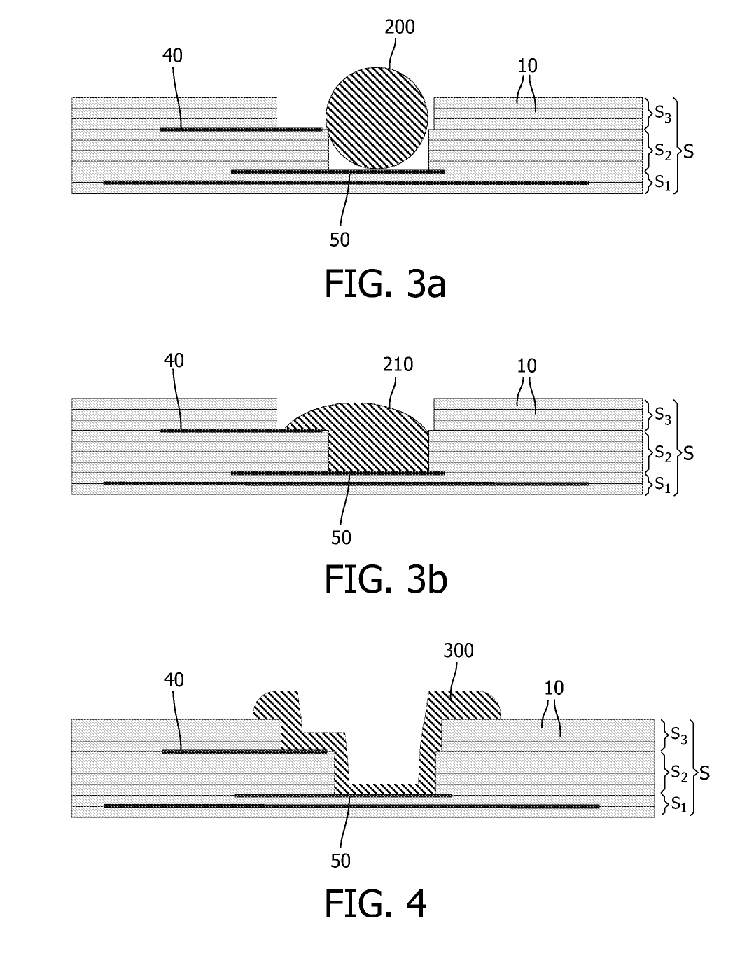

FIGS. 3a and 3b show an embodiment of the inter-layer connections

FIG. 4 shows another embodiment of the inter-layer connections

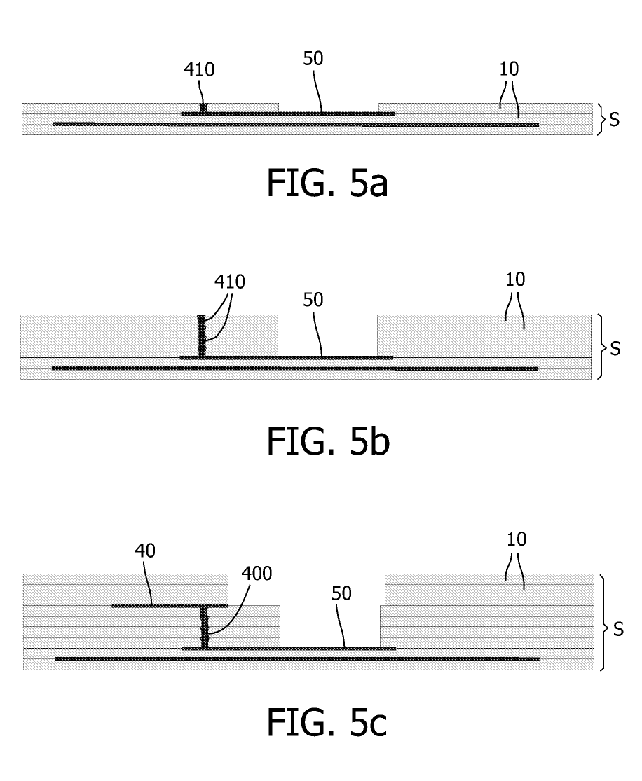

FIGS. 5a, 5b and 5c show a further embodiment of the inter-layer connections

The present invention will be described with respect to particular embodiments and with reference to certain drawings but the invention is not limited thereto but only by the claims. Any reference signs in the claims shall not be construed as limiting the scope. The drawings described are only schematic and are non-limiting. In the drawings, the size of some of the elements may be exaggerated and not drawn on scale for illustrative purposes. Where the term “comprising” is used in the present description and claims, it does not exclude other elements or steps. Where an indefinite or definite article is used when referring to a singular noun e.g. “a” or “an”, “the”, this includes a plural of that noun unless something else is specifically stated.

Furthermore, the terms first, second, third and the like in the description and in the claims, are used for distinguishing between similar elements and not necessarily for describing a sequential or chronological order. It is to be understood that the terms so used are interchangeable under appropriate circumstances and that the embodiments of the invention described herein are capable of operation in other sequences than described or illustrated herein.

Moreover, the terms top, bottom, first, second and the like in the description and the claims are used for descriptive purposes and not necessarily for describing relative positions. It is to be understood that the terms so used are interchangeable under appropriate circumstances and that the embodiments of the invention described herein are capable of operation in other orientations than described or illustrated herein.

FIG. 1 shows a set S of flexible foils 10 each comprising an isolating layer 30 between two conductive layers 20. These flexible foils can be used to build MEMS devices in an easy way as described in the European patent application 05108280.8 filed on Sep. 9, 2005 with the title “A method of manufacturing a microsystem, such a microsystem, a stack of foils comprising such a microsystem, an electronic device comprising such a microsystem and use of the electronic device”.

FIGS. 2a and 2b show an inter-layer connection as described in the European patent application 05108280.8 filed on Sep. 9, 2005 with the title “A method of manufacturing a microsystem, such a microsystem, a stack of foils comprising such a microsystem, an electronic device comprising such a microsystem and use of the electronic device”. The connection within the set S of flexible foils is limited to two adjacent layers 10 where the conductive layers 20 overlap and are in direct contact with each as can be seen in the enlarged illustration of FIG. 2a given by FIG. 2b.

FIGS. 3a and 3b show one embodiment of the invention where a set S of flexible foils 10 is stacked on each other. The set S comprises three subsets S₁, S₂ and S₃. The first subset Sᵢ comprises two flexible foils at the bottom of the set whereby a second patterned conductive layer 50 is on top of the subset S₁. The second subset S₂ comprises four patterned flexible foils 10, each of the flexible foils 10 has an opening and the openings of the four foils are aligned to each other. The second subset S₂ is stacked on top of the first subset S1 in a way that second patterned conductive layer 50 on top of the first subset S₁ is accessible from top side of the set S via the aligned openings of the four foil of the subset S₂. The aligned openings of the second subset S₂ form a contact hole to the second patterned conductive layer 50. Further, the top foil of the second subset S₂ comprises a first patterned conductive layer 40 extending up to the vicinity of the contact hole in the second subset S₂. The third subset S₃ stacked on top of the second subset S₂ comprises three patterned layers of flexible foils 10, each of the flexible foils 10 has an opening with a bigger extension as the opening of each of the foils comprised by the second subset S₂ and the openings of the three foils are aligned to each other. The aligned openings of the third subset S₃ are aligned with the contact hole of the second subset S₂ in a way that the first patterned conductive layer 40 on top of the second subset S₂ is accessible from the top of the set S via the aligned openings in the subset S₃ due to the bigger extension of this aligned openings in the subset S₃ in comparison to the contact hole in the subset S₂. A solder ball 200 is placed within the contact hole on top of the patterned conductive layer 50 as shown in FIG. 3a. In FIG. 3b the situation is shown after heating up the set S of stacked foils and the solder ball 200. The solder ball 200 of FIG. 3a was melted building a conductive inter-layer connection 210 connecting the second patterned conductive layer 50 and the first patterned conductive layer 40.

FIG. 4 shows another embodiment of the invention. Again a set S of flexible foils 10 is stacked on each other I the same way as described in the description of FIGS. 3a and 3b above. Instead of a solder ball 200 a conductive layer has been deposited by means of sputtering or evaporation techniques on top of the set S of stacked flexible foils 10. In a following step the conductive layer has been patterned using e.g. lithographic technologies in a way that the patterned conductive inter-layer connection 300 covers the opening and connects the second patterned conductive layer 50 and the first patterned conductive layer 40 in a conductive way.

A further embodiment of the invention is shown in FIGS. 5a, 5b and 5c. FIG. 5a shows a set S of stacked flexible foils 10 with one flexible foil 10 having a carbonized part 410 extending through the whole thickness of the flexible foil 10. The carbonization can e.g. be done by means of a laser heating up the flexible foil 10 at a certain area in a reducing atmosphere. The flexible foil 10 with the carbonized part 410 is stacked on another flexible foil 10 with a patterned conductive layer 50 whereby the patterned conductive layer 50 is in contact with the surface of the carbonized part 410 on the bottom side of the flexible foil 10. Further flexible foils 10 with carbonized parts 410 can be stacked on each other in a way that the surface of the carbonized part 410 on the top side of a first flexible foil 10 is in contact with surface of the carbonized part 410 on the bottom side of a flexible foil 10 stacked on top of the first flexible foil 10 as shown in FIG. 5b. FIG. 5c shows that a further flexible foil 10 with a patterned conductive layer 40 is stacked on a flexible foil 10 with a carbonized part 410 being in contact with other carbonized parts 410 of other flexible foils and the patterned conductive layer 50 is also in contact with the surface of the carbonized part 410 of a flexible foil 10. After bonding the set S of stacked flexible foils 10 together by e.g. heat and pressure a conductive inter-layer connection 400 is formed between the patterned conductive layer 40 and the patterned conductive layer 50 by means of the carbonized parts 410 of the flexible foils 10.

1. A method of manufacturing inter-layer connections in a microsystem with a space, which method comprises the following steps:
providing a set of at least two electrically insulating flexible foils, wherein the individual flexible foils comprise the same foil material, and wherein a conductive layer is present on at least one side of at least two flexible foils, and wherein said conductive layers are suitable for use as an electrode or a conductor;
patterning the conductive layers so as to form electrodes or conductors;
patterning at least one flexible foil, in such a manner that at least one opening is formed;
stacking the set of flexible foils;
joining the flexible foils together;
providing an electrically conducting inter-layer connections between at least two patterned conductive layers separated by means at least one isolating layer of the flexible foils.

2. A method as claimed in claim 1, further comprising the steps of
positioning at least one opening in the at least one first patterned flexible foil supposed to be a contact hole in a way that a second conductive layer on a second flexible foil is accessible through the contact hole, and a first patterned conductive layer on the at least one first patterned flexible foil extends to the contact hole and is also accessible;
providing an electrically conductive contact between the first patterned conductive layer and the second conducive layer through the contact hole by filling a conductive material in the contact hole.

3. A method as claimed in claim 2, characterized in that the conductive material is a material used for soldering.

4. A method as claimed in claim 3, further comprising the steps of
placing a solder ball in the at least one opening;
heating the stack of at least two flexible foils until the solder material flows and a conductive inter-layer connection connects the first patterned conductive layer and the second conductive layers in a electrically conductive way.

5. A method as claimed in claim 2, further comprising the steps of
evaporating or sputtering the electrically conductive material;
patterning said conductive material in a way that the electrically conductive inter-layer connection is formed.

6. A method as claimed in claim 1, further comprising the step of carbonizing of the flexible foils in a way that at least one electrically conductive inter-layer connection is formed.

7. A method as claimed in claim 6, further comprising the step of
carbonizing at least one part of a first flexible foil with a laser;
stacking the first flexible foil on a second flexible foil with a conductive layer extending to and covering at least a part of the surface of the at least one carbonized part of the first flexible foil;
further stacking a third flexible foil with a patterned conductive layer extending to and covering at least a part of the surface of the carbonized part of the flexible foil in a way that there is at least one electrically conductive inter-layer connection.

8. A method as claimed in claim 1, characterized in that the material for the conductive layer is selected from the group consisting of aluminum, platinum, silver, gold, copper, indium tin oxide and tantalum.

9. A method as claimed in claim 1, characterized in that the material of the isolating layer of the flexible foil is selected from the group consisting of polyphenyl sulphide (PPS) and polyethylene terephthalate (PET).

10. A method as claimed in claim 1, characterized in that the flexible foil has a thickness between 1 μm and 5 μm.

11. A microsystem built by a set of at least two electrically insulating flexible foils stacked one on top of the other, wherein the individual flexible foils comprise the same foil material, wherein at least two foils are provided with a patterned conductive layer, which are arranged as electrodes, wherein at least one foil is provided with a space, and wherein at least two electrodes separated by means of at least one isolating layer are connected by means of an electrically conductive inter-layer connection.
